(19) United States
(12) Patent Application Publication
(10) Pub. No.: US 2024/0006158 A1
(43) Pub. Date: Jan. 4, 2024

(54) CO-DOPING TO CONTROL WET ETCH RATE OF FCVD OXIDE LAYERS

(71) Applicant: Applied Materials, Inc., Santa Clara, CA (US)

(72) Inventors: Vikram M. Bhosle, North Reading, MA (US); Timothy J. Miller, Ipswich, MA (US); Jun Seok Lee, Andover, MA (US); Deven Raj Mittal, Middleton, MA (US)

(73) Assignee: Applied Materials, Inc., Santa Clara, CA (US)

(21) Appl. No.: 17/854,456

(22) Filed: Jun. 30, 2022

(51) Int. Cl. H01J 37/32; H01L 21/3115; H01L 21/66

(52) U.S. Cl. CPC H01J 37/32412; H01J 37/3244; H01J 37/32981; H01J 37/32697; H01L 21/31155; H01L 22/26; H01J 2237/24585; H01J 2237/3365; H01L 21/31111

(57) ABSTRACT

A method for reducing a wet etch rate of flowable chemical vapor deposition (FCVD) oxide layers in a semiconductor wafer, the method including performing a plasma doping operation on the semiconductor wafer using a primary dopant gas and a diluent gas adapted to reduce a wet etch rate of the FCVD oxide layer, wherein the dopant gas and the diluent gas are supplied by a gas source of a plasma doping system, wherein the diluent gas is provided in an amount of 0.01%-5% by volume of the total amount of gas supplied by the gas source 36 during the plasma doping operation, and wherein the primary dopant gas is He and the diluent gas is selected from a group including of CH4, CO, CO2, and CF2.

### FIELD OF THE DISCLOSURE

Embodiments of the present disclosure relate to semiconductor processing techniques, and more particularly, to methods for reducing the wet etch rate of flowable chemical vapor deposition oxide layers during semiconductor device fabrication.

### BACKGROUND OF THE DISCLOSURE

As semiconductor devices continue to scale to smaller dimensions, the patterning of surface features in semiconductor substrates employed in such devices becomes increasingly difficult due to the small size and dense packing of such features. For example, in the manufacture of fin field-effect transistor (FinFET) devices, it has become challenging to form nanometer-scale trench features in semiconductor substrates using conventional processes while avoiding so-called “tip-to-tip shorting” resulting from the inadvertent removal of dielectric isolation layers between adjacent fins during certain wet etch processes. Tip-to-tip shorting in FinFET devices may be detrimental to the overall performance of a device and is therefore undesirable.

A need exists for efficient, inexpensive processes for mitigating wet etching of dielectric isolation layers to prevent undesirable phenomena such as tip-to-tip shorting. With respect to these and other considerations, the present improvements may be useful.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A method for reducing a wet etch rate of flowable chemical vapor deposition (FCVD) oxide layers in a semiconductor wafer in accordance with an exemplary embodiment of the present disclosure may include performing a plasma doping operation on the semiconductor wafer using a primary dopant gas and a diluent gas adapted to reduce a wet etch rate of the FCVD oxide layer, wherein the dopant gas and the diluent gas are supplied by a gas source of a plasma doping system, and wherein the diluent gas is provided in an amount of 0.01%-5% by volume of the total amount of gas supplied by the gas source during the plasma doping operation.

A system for reducing a wet etch rate of flowable chemical vapor deposition (FCVD) oxide layers in a semiconductor wafer in accordance with an exemplary embodiment of the present disclosure may include a plasma doping chamber defining an enclosed volume, and a platen positioned within the plasma doping chamber for supporting the semiconductor wafer, wherein an interior component of the system located within the plasma doping chamber is adapted to release carbon molecules into the chamber when subjected to a plasma doping operation.

Another method for reducing a wet etch rate of flowable chemical vapor deposition (FCVD) oxide layers in a semiconductor wafer in accordance with an exemplary embodiment of the present disclosure may include pre-coating the semiconductor wafer with a layer of carbon, and performing a plasma doping operation on the semiconductor wafer using a primary dopant gas, causing carbon from the layer of carbon to be knocked into the semiconductor wafer.

### BRIEF DESCRIPTION OF THE DRAWINGS

By way of example, various embodiments of the disclosed techniques will now be described with reference to the accompanying drawings, wherein:

FIG. 1 is a schematic cross-sectional view illustrating a plasma doping system in accordance with an exemplary embodiment of the present disclosure;

FIG. 2 is a schematic cross-sectional view illustrating a method of operating the plasma doping system shown in FIG. 1;

FIG. 3 is a schematic cross-sectional view illustrating another method of operating the plasma doping system shown in FIG. 1;

FIG. 4 is a top view illustrating an exemplary embodiment of a shield ring of the plasma doping system shown in FIG. 1;

FIG. 5 is a top view illustrating another exemplary embodiment of a shield ring of the plasma doping system shown in FIG. 1;

FIG. 6 is a top view illustrating an exemplary embodiment of a wafer to be processed by the plasma doping system shown in FIG. 1.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

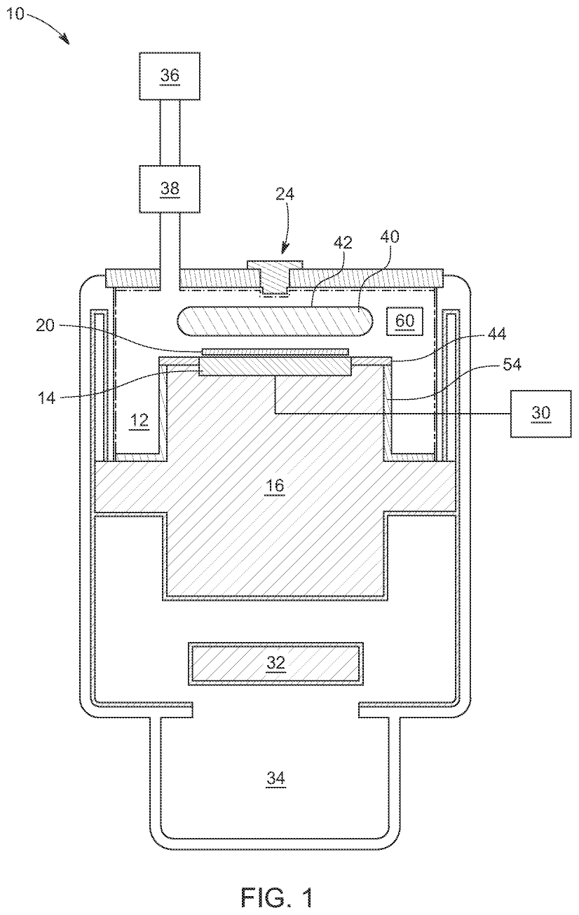

Referring to FIG. 1, an exemplary embodiment of a plasma doping system 10 (hereinafter “the system 10”) in accordance with the present disclosure is shown. The system 10 may include a plasma doping chamber 12 (hereinafter “the chamber 12”) defining an enclosed volume. A platen 14 supported by a pedestal 16 may be positioned within the chamber 12 and may provide a surface for holding a workpiece, such as a semiconductor wafer 20. The wafer 20 may, for example, be clamped at its periphery to a flat surface of the platen 14. The platen 14 may support the wafer 20 and may provide an electrical connection to the wafer 20. In various embodiments, the platen 14 may include conductive pins for providing an electrical connection to the wafer 20. The present disclosure is not limited in this regard. The platen 14 may further including heating elements for heating the wafer 20.

The wafer 20 may be electrically connected to a high voltage pulse generator 30 via the platen 14, and the wafer 20 may function as a cathode. The enclosed volume of the chamber 12 may be coupled through a controllable valve 32 to a vacuum pump 34. A gas source 36 may be coupled to the chamber 12 via a mass flow controller 38. The gas source 36 may supply an ionizable gas containing a desired dopant for implantation into the wafer 20, and the mass flow controller 38 may regulate the rate gas is supplied to the chamber 12 as further described below.

During operation of the system 10, the wafer 20 may be positioned on the platen 14, and the gas source 36 may provide a gas containing a desired dopant species to the chamber 12 via the mass flow controller 38. The pulse generator 30 may apply a series of high voltage pulses to the wafer 20, causing formation of a plasma 40 between the wafer 20 and a radio frequency inductively coupled plasma (RF ICP) source 24 above the wafer 20. As known in the art, the plasma 40 contains positive ions of the ionizable gas from the gas source 36. The plasma 40 further includes a plasma sheath 42 in the vicinity of the platen 14. The electric field present between the RF ICP source 24 and the platen 14 during the high voltage pulse accelerates positive ions from the plasma 40 across the plasma sheath 42 toward the platen 14. The accelerated ions are implanted into the wafer 20 to form regions of impurity material. The system 10 may further include an annular shield ring 44 surrounding the platen 14. The shield ring 44 may be electrically biased to extend the plasma sheath 42 beyond the edge of the wafer 20 to ensure complete and uniform doping.

In accordance with the present disclosure, the system 10 described above may be employed to dope the wafer 20 with precisely controlled, low concentrations of a dopant (e.g., carbon) adapted to make portions of the wafer 20 less susceptible to etching. For example, the wafer 20 may include surface features such as fins with trenches formed therebetween. The fins and the trenches may be coated/filled with a dielectric material such as a flowable chemical vapor deposition (FCVD) oxide layer for providing electrical isolation between the surface features. When the wafer 20 is subjected to certain etching processes, such as wet etching processes for removing hardmask layers and the like, the FCVD oxide layer should be preserved to maintain the electrical isolation between the surface features to prevent undesirable phenomena such as tip-to-tip shorting. Various approaches for doping the wafer 20 to reduce the wet etch rate of the FCVD oxide layer will now be described.

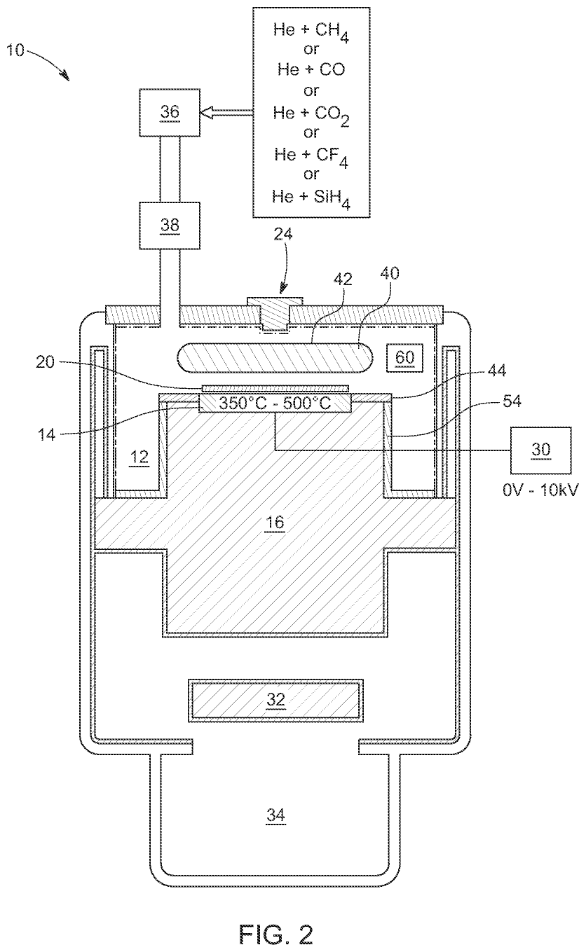

Referring to FIG. 2, a first approach for doping the wafer 20 to make an FCVD oxide layer on the wafer 20 less susceptible to etching is illustrated. In this approach, the gas source 36 may supply a primary dopant gas as well as a diluent gas to the chamber 12 as further described below. Additionally, the wafer 20 may be heated (via the platen 14) to a temperature in a range of 350 degrees C.-500 degrees C. and may be subjected to an electrical bias (via the pulse generator 30) in a range of 0V-10 KV. The primary dopant gas and the diluent gas may be provided separately (i.e., from two different sources or bottles) or may be provided together (e.g., in a common, premixed bottle). The present disclosure is not limited in this regard.

In various embodiments the primary dopant gas may be He, selected for its ability to outgas undesired elements (e.g., hydrogen) from the wafer 20 (as well as outgas itself). The present disclosure is not limited in this regard. The diluent gas may be a species selected for its ability to reduce a wet etch rate of the FCVD oxide layer on the wafer 20 when implanted therein. In various non-limiting embodiments, the diluent gas may be a carbon-containing gas such as CH₄, CO, CO2, or CF₂. In other embodiments, the diluent gas may be SiH₄. The present disclosure is not limited in this regard. The diluent gas may be provided in an amount of 0.01%-5% by volume of the total amount of gas supplied to the chamber 12 by the gas source 36. The molecules of the diluent gas may contribute to the ionized species in the plasma 40, resulting in ions of such species being implanted into the wafer 20. This implantation, when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20.

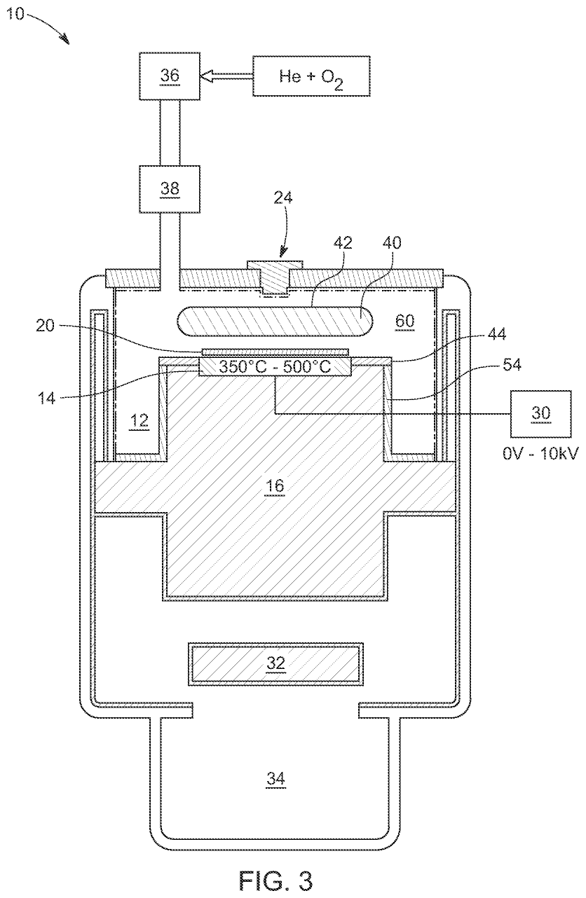

Referring to FIG. 3, a second approach for doping the wafer 20 to make an FCVD oxide layer on the wafer 20 less susceptible to etching is illustrated. In this approach, the gas source 36 may supply a primary dopant gas as well as oxygen as a diluent gas to the chamber 12. Additionally, the wafer 20 may be heated (via the platen 14) to a temperature in a range of 350 degrees C.-500 degrees C. and may be subjected to an electrical bias (via the pulse generator 30) in a range of 0V-10 KV. The primary dopant gas and the diluent gas may be provided separately (i.e., from two different sources or bottles) or may be provided together (e.g., in a common, premixed bottle). The present disclosure is not limited in this regard.

In various embodiments the primary dopant gas may be He, selected for its ability to outgas undesired contaminants (e.g., hydrogen) from the wafer 20 (as well as outgas itself). The present disclosure is not limited in this regard. The diluent gas may be 02 provided in an amount of 0.01%-5% by volume of the total amount of gas supplied to the chamber 12 by the gas source 36. The oxygen molecules in the diluent gas may contribute to the ionized species in the plasma 40, resulting in oxygen ions be implanted into the wafer 20. The oxygen may react with the composition of the wafer 20 and may cause carbon molecules contained within the wafer to be released into the chamber 12. The oxygen may also react with other carbon surfaces in the chamber 12 (e.g., a graphite chamber liner 54 in the chamber 12) and may cause carbon molecules contained within such surfaces to be released into the chamber 12. These carbon molecules may contribute to the ionized species in the plasma 40, resulting in carbon ions be implanted into the wafer 20. This low level of carbon doping, when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20.

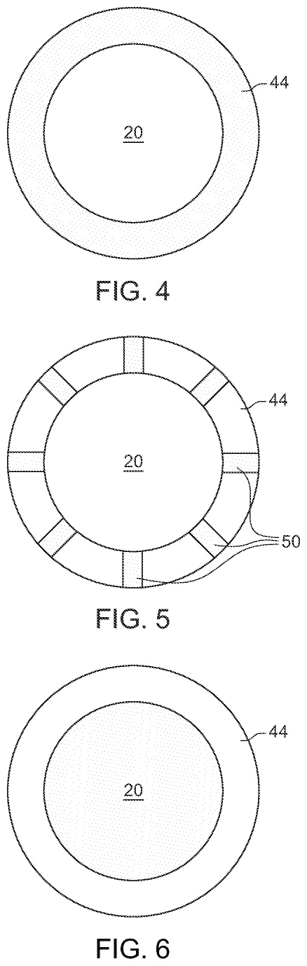

Referring to FIGS. 1 and 4, a third approach for doping the wafer 20 to make an FCVD oxide layer on the wafer 20 less susceptible to etching may include providing the system 10 with a shield ring 44 previously doped with carbon. For example, the shield ring 44 may be formed of carbon-doped silicon. The present disclosure is not limited in this regard. Additionally, the wafer 20 may be heated (via the platen 14) to a temperature in a range of 350 degrees C.-500 degrees C. and may be subjected to an electrical bias (via the pulse generator 30) in a range of 0V-10 KV as in the approaches described above.

When a doping process is performed on the wafer 20 (e.g., He doping), accelerated dopant ions may strike the shield ring 44, causing carbon molecules in the shield ring 44 to be sputtered into the chamber 12. These carbon molecules may contribute to the ionized species in the plasma 40, resulting in carbon ions be implanted into the wafer 20. This low level of carbon doping, when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20.

Referring to FIGS. 1 and 5, a fourth approach for doping the wafer 20 to make an FCVD oxide layer on the wafer 20 less susceptible to etching may include providing the system 10 with a shield ring 44 having graphite strips 50 disposed on a top surface thereof. For example, as depicted in FIG. 4, the shield ring 44 may be formed of silicon and may have a plurality of radially extending, circumferentially spaced graphite strips 50 applied to its top surface. The shield ring 44 is shown as having a total of 8 graphite strips 50. The present disclosure is not limited in this regard, and the number, size, and shape of the graphite strips 50 can be varied to suit a particular application. Additionally, the wafer 20 may be heated (via the platen 14) to a temperature in a range of 350 degrees C.-500 degrees C. and may be subjected to an electrical bias (via the pulse generator 30) in a range of 0V-10 KV as in the approaches described above.

When a doping process is performed on the wafer 20 (e.g., He doping), accelerated dopant ions may strike the graphite strips 50 on the shield ring 44, causing carbon molecules in the graphite strips to be sputtered into the chamber 12. These carbon molecules may contribute to the ionized species in the plasma 40, resulting in carbon ions be implanted into the wafer 20. This low level of carbon doping, when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20. Notably, the size of the graphite strips 50 may be varied to control the amount of carbon sputtered into the chamber 12 and implanted into the wafer 20 during processing.

Referring to FIGS. 1 and 6, a fifth approach for doping the wafer 20 to make an FCVD oxide layer on the wafer 20 less susceptible to etching may include pre-coating the wafer 20 with carbon. For example, a thin layer of carbon may be sprayed on or otherwise applied to a top surface of the wafer 20 prior to the wafer 20 being placed in the chamber 12 for processing. In various non-limiting embodiments, the layer of carbon may have a thickness in a range of 10-10000 Angstroms. Once in the chamber 12, the wafer 20 may be heated (via the platen 14) to a temperature in a range of 350 degrees C.-500 degrees C. and may be subjected to an electrical bias (via the pulse generator 30) in a range of 0V-10 KV as in the approaches described above.

When a doping process is performed on the wafer 20 (e.g., He doping), accelerated dopant ions may strike the carbon layer on the wafer 20 and may knock carbon into the wafer 20. Additionally, carbon molecules may be sputtered from the carbon layer into the chamber 12 and may contribute to the ionized species in the plasma 40, resulting in carbon ions be implanted into the wafer 20. This low level of carbon doping (resulting from knock-in and ion implantation), when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20. Notably, the amount of carbon in the pre-coating applied to the wafer 20 may be varied to control the amount of carbon knocked into the wafer 20 as well as the amount of carbon sputtered into the chamber 12 and implanted into the wafer 20 during processing.

Referring again to FIG. 1, a sixth approach for doping the wafer 20 to make an FCVD oxide layer on the wafer 20 less susceptible to etching may include forming various interior components of the system 10 (i.e., components located within the chamber 12) of graphite or coating the surfaces of such components with graphite. For example, the chamber liner 54 may be formed of graphite. Additionally or alternatively, the pedestal 16 may be coated with graphite. The present disclosure is not limited in this regard. Additionally, the wafer 20 may be heated (via the platen 14) to a temperature in a range of 350 degrees C.-500 degrees C. and may be subjected to an electrical bias (via the pulse generator 30) in a range of 0V-10 KV as in the approaches described above.

When a doping process is performed on the wafer 20 (e.g., He doping), accelerated dopant ions may strike the graphite surfaces in the chamber 12, causing carbon molecules in such surfaces to be sputtered into the chamber 12. These carbon molecules may contribute to the ionized species in the plasma 40, resulting in carbon ions be implanted into the wafer 20. This low level of carbon doping, when performed in combination with heating and biasing the wafer 20 as described above, may make the FCVD oxide layer on the surface of wafer 20 less susceptible to subsequent etching operations. For example, the wet etch rate of the FCVD oxide layer may be significantly reduced, and electrical isolation between surface features (e.g., fins and trenches) on the wafer 20 may thus be preserved after a wet etch process is performed on the wafer 20.

In any of the approaches described above, real-time monitoring of carbon levels in the wafer 20 may be performed during the doping process and such information may be used in a feedforward manner to regulate an amount of carbon being implanted into the wafer 20 to achieve a desired wet etch rate. For example, depending on the measured amount of carbon in the wafer 20, the mass flow controller 38 may be operated to increase or decrease the amount of primary dopant gas and/or diluent gas fed into the chamber 12. In other examples, depending on the measured amount of carbon in the wafer 20, one or more of the RF power, the total implant dose, and the applied electrical bias may be varied. The present disclosure is not limited in this regard.

To facilitate the above-described real-time monitoring of carbon levels in the wafer 20, the system 10 may be provided with various in-situ metrology components 60 adapted to perform such monitoring. Such metrology components may include, and are not limited to, a residual gas analyzer (RGA), an optical omission spectrometer (OES), or a Fourier transform infrared spectrometer. The present disclosure is not limited in this regard.

The embodiments described above provide numerous advantages in the art. For example, the above-described systems and methods provide efficient, inexpensive means for mitigating wet etching of dielectric isolation layers to prevent undesirable phenomena such as tip-to-tip shorting. As a further advantage, the above-described systems and methods can be implemented in-situ before, during, or after standard doping processes without significant modification of existing plasma doping systems.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method for reducing a wet etch rate of flowable chemical vapor deposition (FCVD) oxide layers in a semiconductor wafer, the method comprising:
performing a plasma doping operation on the semiconductor wafer using a primary dopant gas and a diluent gas adapted to reduce a wet etch rate of the FCVD oxide layer, wherein the dopant gas and the diluent gas are supplied by a gas source of a plasma doping system, and wherein the diluent gas is provided in an amount of 0.01%-5% by volume of a total amount of gas supplied by the gas source during the plasma doping operation.

2. The method of claim 1, wherein the primary dopant gas is He and the diluent gas is a carbon-containing gas.

3. The method of claim 2, wherein the diluent gas is selected from a group consisting of CH4, CO, CO2, and CF2.

4. The method of claim 1, wherein the diluent gas is oxygen.

5. The method of claim 1, wherein the dopant gas and the diluent gas are provided to the gas source in separate containers.

6. The method of claim 1, wherein the dopant gas and the diluent gas are provided to the gas source in a common, pre-mixed container.

7. The method of claim 1, further comprising heating the wafer to a temperature in a range of 350 degrees C.-500 degrees C.

8. The method of claim 1, further comprising subjecting the wafer to an electrical bias in a range of 0V-10 KV.

9. The method of claim 1, further comprising:
monitoring carbon levels in the semiconductor wafer; and
based on the monitored levels of carbon in the semiconductor wafer, varying the amount of one of at least one of the primary dopant gas and the diluent gas supplied by the gas source.

10. A system for reducing a wet etch rate of flowable chemical vapor deposition (FCVD) oxide layers in a semiconductor wafer, the system comprising:
a plasma doping chamber defining an enclosed volume; and
a platen positioned within the plasma doping chamber for supporting the semiconductor wafer;
wherein an interior component of the system located within the plasma doping chamber is adapted to release carbon molecules into the chamber when subjected to a plasma doping operation.

11. The system of claim 10, wherein the interior component is a shield ring surrounding the platen.

12. The system of claim 11, wherein the shield ring is doped with carbon.

13. The system of claim 12, wherein the shield ring is formed of carbon-doped silicon.

14. The system of claim 11, wherein the shield ring is provided with a plurality of graphite strips disposed on a top surface thereof.

15. The system of claim 14, wherein the graphite strips are disposed on the shield ring in a radially extending, circumferentially spaced arrangement.

16. The system of claim 10, wherein the interior component is a liner of the plasma doping chamber.

17. A method for reducing a wet etch rate of flowable chemical vapor deposition (FCVD) oxide layers in a semiconductor wafer, the method comprising:
pre-coating the semiconductor wafer with a layer of carbon; and
performing a plasma doping operation on the semiconductor wafer using a primary dopant gas, causing carbon from the layer of carbon to be knocked into the semiconductor wafer.

18. The method of claim 17, wherein the layer of carbon has a thickness in a range of 10-10000 Angstroms.

19. The method of claim 17, further comprising heating the semiconductor wafer to a temperature in a range of 350 degrees C.-500 degrees C.

20. The method of claim 17, further subjecting the semiconductor wafer to an electrical bias in a range of 0V-10 KV.
